(19) United States
(12) Patent Application Publication
(10) Pub. No.: US 2025/0172588 A1
(43) Pub. Date: May 29, 2025

(54) PROBE CARD

(71) Applicant: Unimicron Technology Corp., Taoyuan City (TW)

(72) Inventors: Chih-Peng Hsieh, Taoyuan City (TW); Chihmin Yang, Taoyuan City (TW); Fang-I Hsu, Taoyuan City (TW)

(73) Assignee: Unimicron Technology Corp., Taoyuan City (TW)

(21) Appl. No.: 18/408,489

(22) Filed: Jan. 9, 2024

(30) Foreign Application Priority Data
Nov. 24, 2023 (TW) 112145557

(51) Int. Cl. G01R 1/073

(52) U.S. Cl. CPC G01R 1/07342

(57) ABSTRACT

A probe card includes an adapter plate, a guide plate, a plurality of probes, at least one capacitor and a conductive layer. The adapter plate includes at least one power pad and at least one ground pad. The guide plate is disposed between the adapter plate and a device under test. The probes penetrate through the guide plate and are electrically connected to the adapter plate. The probes include at least one power probe and at least one ground probe. The power probe is electrically connected to the power pad, and the ground probe is electrically connected to the ground pad. The capacitor is located on at least a portion of the power probe. The conductive layer is connected to the guide plate. The capacitor connects the power probe and the ground probe in series through the conductive layer to form a current loop.

### CROSS-REFERENCE TO RELATED APPLICATION

This application claims the priority benefit of Taiwan application serial no. 112145557, filed on Nov. 24, 2023. The entirety of the above-mentioned patent application is hereby incorporated by reference herein and made a part of this specification.

### BACKGROUND

### Technical Field

The disclosure relates to a test device, and more particularly, to a probe card.

### Description of Related Art

Generally speaking, the test machine provides voltage/current to the device under test (DUT) end when the prober card is tested. When the current drawn by the integrated circuit (IC) is too fast or too large, the power supply will easily produce an instantaneous voltage drop (AC Voltage Drop). At this time, the machine will provide a compensation current. Due to the large parasitic inductance between the machine and the device under test, the compensation current cannot reach the device under test in time, so the de-coupling capacitor is usually placed close to the device under test, such as on an adapter plate or the printed circuit board. However, this will make the design of the probe stuck on the wiring difficult, and the inductance of the probe path can only be improved by selecting shorter pins. Therefore, how to reduce the parasitic effect of the probe between the device under test and the de-coupling capacitor path is the main issue at this stage to improve power integrity (PI).

### SUMMARY

The disclosure provides a probe card that improves test signals integrity.

The probe card of the disclosure is configured to test an electrical properties of a device under test. The probe card includes an adapter plate, a guide plate, a plurality of probers, at least one capacitor and a conductive layer. The adapter plate includes at least one power pad and at least one ground pad. The guide plate is disposed between the adapter plate and the device under test. The plurality of probes penetrate through the guide plate and are electrically connected to the adapter plate. The plurality of probes include at least one power prober and at least one ground prober. The at least one power prober is electrically connected to the at least one power pad, and the at least one ground probe is electrically connected to the at least one ground pad. The at least one capacitor is located on at least a portion of the at least one power prober. The conductive layer is connected to the guide plate, wherein the at least one capacitor connects the at least one power prober and the at least one ground prober in series through the conductive layer to form a current loop.

In an embodiment of the disclosure, the probe card further includes a dielectric layer and at least one metal layer. The dielectric layer is located on the at least a portion of the at least one power probe. The at least one metal layer is disposed on the dielectric layer. When the at least one metal layer is a metal layer, the dielectric layer and the metal layer are sequentially stacked on the at least portion of the at least one power prober, and the at least portion of the at least one power prober, the dielectric layer and the metal layer define the at least one capacitor, or, when the at least one metal layer is two metal layers, the dielectric layer is located between the two metal layers, and the two metal layers and the dielectric layer define the at least one capacitor.

In an embodiment of the disclosure, the guide plate includes a first guide plate portion and a second guide plate portion. The first guide plate portion and the second guide plate portion are disposed in a hollow ring shape at intervals. The second guide plate portion is located between the first guide plate portion and the device under test. The at least one power prober includes at least one fixed end and at least one detection end. The at least one fixed end is connected to the at least one power pad, and the at least one detection end is used to contact the device under test.

In an embodiment of the disclosure, the conductive layer is disposed on an exterior surface of the first guide plate portion relatively adjacent to the adapter plate, and the at least one capacitor penetrates the first guide plate portion and is adjacent to the at least one fixed end.

In an embodiment of the disclosure, the conductive layer is disposed on an exterior surface of the second guide plate portion relatively away from the adapter plate, and the at least one capacitor penetrates the second guide plate portion and is adjacent to the at least one detection end.

In an embodiment of the disclosure, the probe card further includes an another conductive layer, wherein the conductive layer is connected to an inside of the first guide plate portion, and the another conductive layer is connected to an inside of the second guide plate portion, and the at least one capacitor penetrates the another conductive layer.

In an embodiment of the disclosure, the at least one capacitor includes at least one first capacitor and at least one second capacitor, the at least one first capacitor penetrates the conductive layer, and the at least one second capacitor penetrates another conductive layer.

In an embodiment of the disclosure, the at least one first capacitor further penetrates the first guide plate portion and extends adjacent to the at least one power pad.

In an embodiment of the disclosure, the second guide plate portion has at least one first opening, the conductive layer is disposed on an exterior surface of the second guide plate portion relatively far away from the adapter plate and extends into the at least one first opening, and the at least one capacitor is located in the at least one the first opening and spaced apart from the conductive layer.

In an embodiment of the disclosure, the probe card further includes another conductive layer. The guide plate further includes a third guide plate portion, and the third guide plate portion has at least one second opening. The at least one second opening is disposed corresponding to the at least one first opening, and a diameter of the at least one second opening is larger than a diameter of the at least one first opening. The another conductive layer is disposed on a surface of the third guide plate portion relatively away from the adapter plate and extends into the at least one second opening, and the at least one capacitor further extends into the at least one second opening and is spaced apart from the another conductive layer.

In an embodiment of the disclosure, the probe card further includes an insulating layer disposed on a portion of each of the plurality of the probes.

Based on the above, in the disclosure, the capacitor on the power prober connects the power prober and the ground prober in series through the conductive layer of the guide plate to form a current loop, wherein the capacitor can provide instant power to the probe card during testing. Compared with the prior art in which the de-coupling capacitor is placed on the adapter plate or the printed circuit board, the design of the probe card 100a in the disclosure can greatly shorten the distance between the power supply and the device under test, not only can instantly supply power, but also reduce parasitic inductance, so that the test high voltage (VIH) can be effectively identified, and the test signal can be avoided to avoid blurring of the test signal that leads to misinterpretation, which can improve the integrity of the test signal.

In order to make the aforementioned features and advantages of the disclosure comprehensible, embodiments accompanied with drawings are described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic diagram of a probe card according to an embodiment of the disclosure.

FIG. 2 is a schematic diagram of a probe card according to another embodiment of the disclosure.

FIG. 3 is a schematic diagram of a probe card according to another embodiment of the disclosure.

FIG. 4 is a schematic diagram of a probe card according to another embodiment of the disclosure.

FIG. 5 is a schematic diagram of a probe card according to another embodiment of the disclosure.

FIG. 6 is a schematic diagram of a probe card according to another embodiment of the disclosure.

FIG. 7A is a schematic diagram of a probe card according to another embodiment of the disclosure.

FIG. 7B is a schematic top view of FIG. 7A.

FIG. 8A is a schematic diagram of a probe card according to another embodiment of the disclosure.

FIG. 8B is a schematic top view of FIG. 8A.

### DESCRIPTION OF THE EMBODIMENTS

The disclosure can be understood by referring to the following detailed description in conjunction with the accompanying drawings. It should be noted that, for the sake of ease of understanding for the reader and for the simplicity of the drawings, the elements in the drawings are not drawn to actual scale. In addition, the number and size of components in the figures are only for illustration and are not intended to limit the scope of the disclosure.

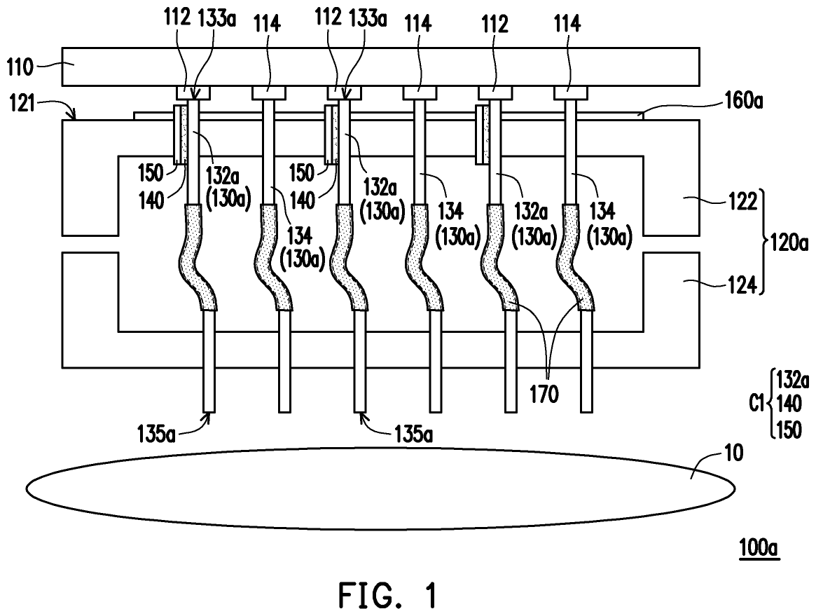

FIG. 1 is a schematic diagram of a probe card according to an embodiment of the disclosure. Please refer to FIG. 1 first. In this embodiment, the prober card 100a is configured to test an electrical properties of a device under test 10. The prober card 100a includes an adapter plate 110, a guide plate 120a, a plurality of probers 130a, at least one capacitor (schematically showing a plurality of capacitor C1) and a conductive layer 160a. The adapter plate 110 includes at least one power pad (schematically showing a plurality of power pads 112) and at least one ground pad (schematically showing a plurality of ground pads 114). The guide plate 120a is disposed between the adapter plate 110 and the device under test 10. The probers 130a penetrate through the guide plate 120a and are electrically connected to the adapter plate 110. The probers 130a include at least one power prober (schematically showing a plurality of power probers 132a) and at least one ground prober (schematically showing a plurality of ground probers 134). The power probes 132a are electrically connected to the power pad 112 respectively. The ground probers 134 are electrically connected to the ground pad 114 respectively. Each capacitor C1 is located on at least a portion of each power probe 132a. The conductive layer 160a is connected to the guide plate 120a, wherein the capacitor C1 connects the power prober 132a and the ground prober 134 in series through the conductive layer 160a to form a current loop.

More specifically, in this embodiment, the guide plate 120a includes a first guide plate portion 122 and a second guide plate portion 124. The shape of the first guide plate portion 122 and the shape of the second guide plate portion 124 are both U-shaped and have a mirrored pattern, wherein the first guide plate portion 122 and the second guide plate portion 124 are spaced apart to form a hollow ring shape. The second guide plate portion 124 is located between the first guide plate portion 122 and the device under test 10. In one embodiment, the guide plate 120a is, for example, a ceramic guide plate, but is not limited thereto.

Each power prober 132a in this embodiment includes a fixed end 133a and a detection end 135a. The fixed end 133a is connected to the power pad 112, and the detection end 135a is used to contact the device under test 10. Furthermore, in this embodiment, the prober card 100a further includes a dielectric layer 140 and at least one metal layer (schematically shown a metal layer 150). The dielectric layer 140 is disposed on at least a portion of each power probe 132a, and the metal layer 150 is disposed on the dielectric layer 140. That is, the dielectric layer 140 and the metal layer 150 are sequentially stacked on at least a portion of each power probe 132a. Herein, at least a portion of each power prober 132a, the dielectric layer 140 and the metal layer 150 define the capacitor C1, and the capacitor C1 is embodied as a parallel plate capacitor. In one embodiment, the dielectric layer 140 is formed on at least a portion of each power probe 132a by deposition, for example, using a high dielectric constant (high Dk) material, but is not limited to this. The metal layer 150 is formed on the dielectric layer 140 by deposition, for example, but is not limited to this.

Please refer to FIG. 1 again. The conductive layer 160a of this embodiment is disposed on an exterior surface 121 of the first guide plate portion 122 relatively adjacent to the adapter plate 110, and the capacitor C1 penetrates the first guide plate portion 122 and the conductive layer 160a and adjacent to the fixed end 133a. In addition, the probe card 100a of this embodiment also includes an insulating layer 170, which is disposed on a portion of each probe 130a.

In short, in this embodiment, the capacitor C1 on the power prober 132a connects the power prober 132a and the ground prober 134 in series through the conductive layer 160a of the guide plate 120a to form a current loop, wherein the capacitor C1 can provide instant power to the probe card 100a during testing. Compared with the prior art in which the de-coupling capacitor is placed on an adapter plate or the printed circuit board, the design of the probe card 100a in this embodiment can greatly shorten the distance between the power supply and the device under test 10, not only can instantly supply power, but also reduce parasitic inductance, so that the test high voltage (VIH) can be effectively identified, and the test signal can be avoided to avoid blurring of the test signal that leads to misinterpretation, which can improve the integrity of the test signal.

It must be noted here that the following embodiments use the component numbers and part of the content of the previous embodiments, where the same numbers are used to represent the same or similar elements, and descriptions of the same technical content are omitted. For descriptions of omitted parts, reference may be made to the foregoing embodiments and will not be repeated in the following embodiments.

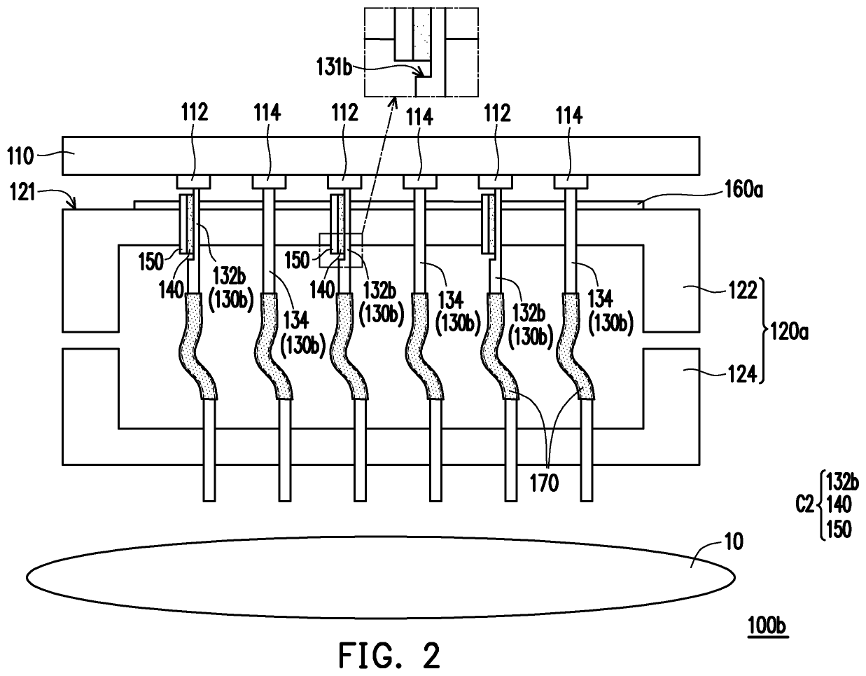

FIG. 2 is a schematic diagram of a probe card according to another embodiment of the disclosure. With reference to both FIG. 1 and FIG. 2, the probe card 100b of this embodiment is similar to the probe card 100a of FIG. 1, and the main difference between the two is that in this embodiment, each power prober 132b of the prober 130b has a groove 131b, and the dielectric layer 140 and the metal layer 150 disposed on the dielectric layer 140 are both located in groove 131b. At least a portion of each power probe 132b, the dielectric layer 140, and the metal layer 150 define the capacitor C2. Herein, the groove 131b can be formed on the power prober 132b through micro-electromechanical technology, laser engraving technology or etching method, but is not limited to this.

It should be noted that in another embodiment not shown, the metal layer can be two metal layers, the dielectric layer is located between the two metal layers, and the two metal layers and the dielectric layer define the capacitor on the power probe, which is still within the scope of the disclosure intended to be protected.

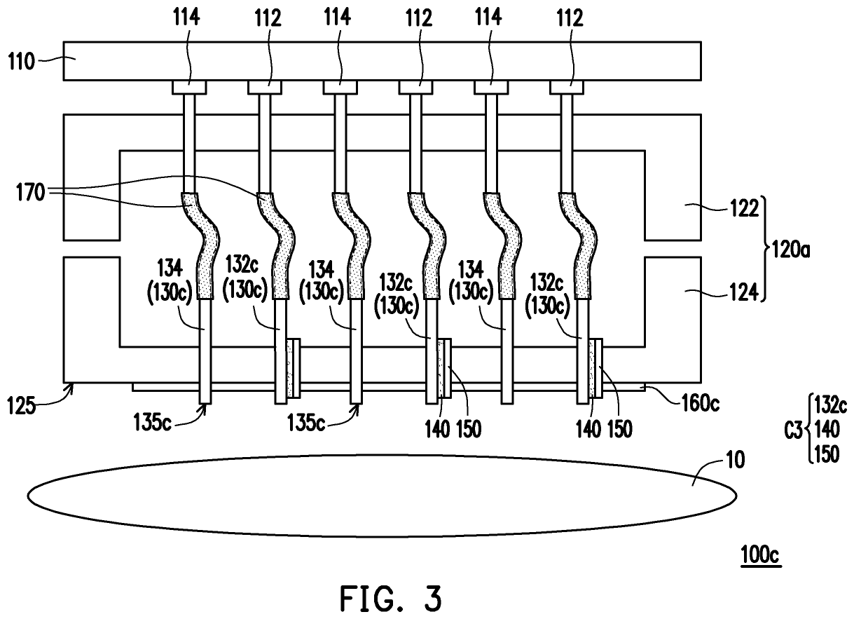

FIG. 3 is a schematic diagram of a probe card according to another embodiment of the disclosure. With reference to both FIG. 1 and FIG. 3, the probe card 100c of this embodiment is similar to the probe card 100a of FIG. 1, and the main difference between the two is that in this embodiment, the conductive layer 160c is disposed on an exterior surface 125 of the second guide plate portion 124 relatively away from the adapter plate 110, and the capacitor C3 defined by at least a portion of each power probe 132c of the probe 130c, the dielectric layer 140, and the metal layer 150 penetrates the second guide plate portion 124 and the conductive layer 160c and is adjacent to the detection end 135c. The setting of this capacitor C3 can be significantly closer to the device under test 10, which can reduce the inductance and improve the test signal integrity and test quality of the probe card 100c.

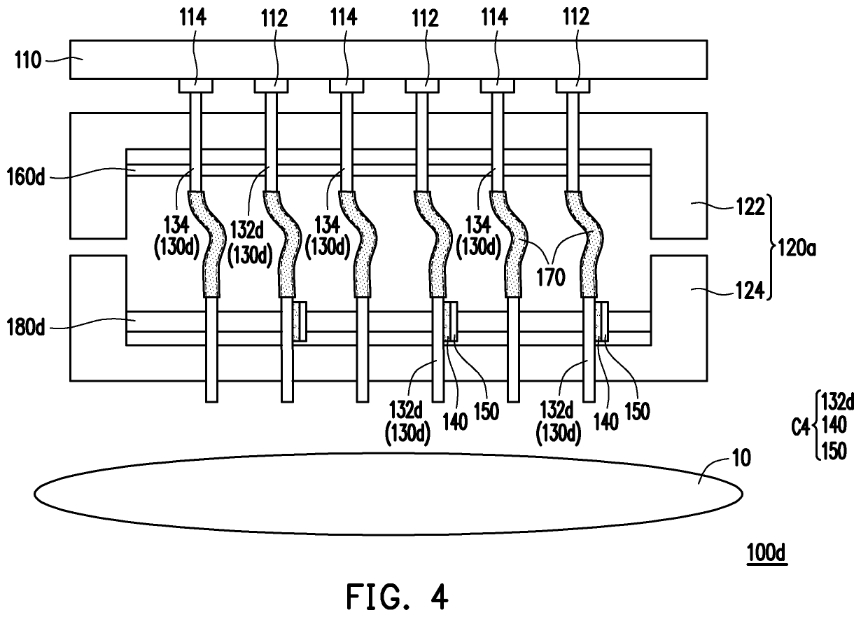

FIG. 4 is a schematic diagram of a probe card according to another embodiment of the disclosure. With reference to both FIG. 1 and FIG. 4, the probe card 100d of this embodiment is similar to the probe card 100a of FIG. 1, and the main difference between the two is that in this embodiment, the prober card 100d also includes an another conductive layer 180d. The conductive layer 160d is connected to an inside of the first guide plate portion 122, and the another conductive layer 180d is connected to an inside the second guide plate portion 124. The capacitor C4 defined by at least a portion of each power prober 132d of the prober 130d, the dielectric layer 140 and the metal layer 150 penetrates the another conductive layer 180d. The setting of this capacitor C4 can be significantly closer to the device under test 10, which can reduce the inductance and improve the test signal integrity and test quality of the probe card 100d.

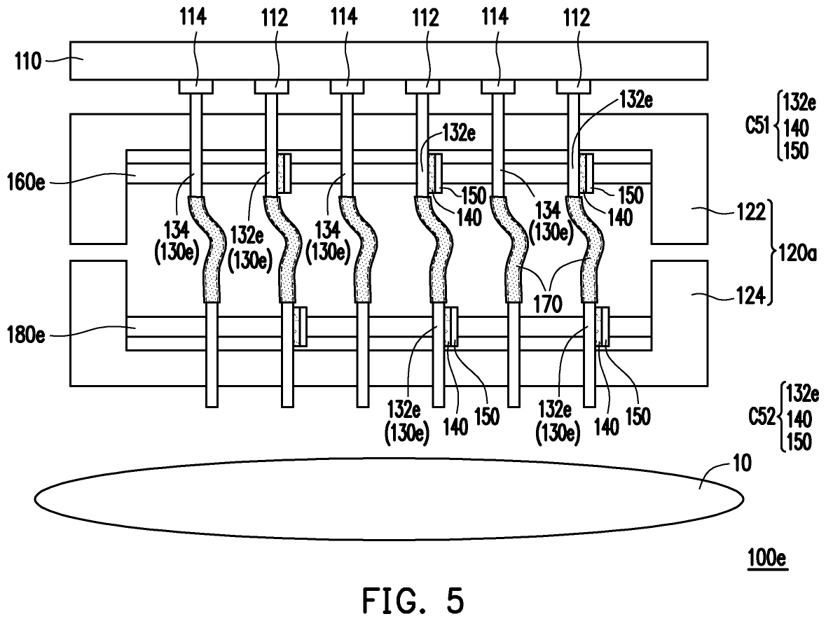

FIG. 5 is a schematic diagram of a probe card according to another embodiment of the disclosure. With reference to both FIG. 4 and FIG. 5, the probe card 100e of this embodiment is similar to the probe card 100d of FIG. 4, and the main difference between the two is that in this embodiment, at least a portion of each power prober 132e of the prober 130e, the dielectric layer 140 and the metal layer 150 may define at least one first capacitor (schematically showing a first capacitor C51) and at least one second capacitor (schematically showing a second capacitor C52). The first capacitor C51 penetrates the conductive layer 160e, and the second capacitor C52 penetrates another conductive layer 180e. The setting of this second capacitor C52 can be significantly closer to the device under test 10, which can reduce the inductance and improve the test signal integrity and test quality of the probe card 100e, while the setting of this first capacitor C51 can increase the capacitor value.

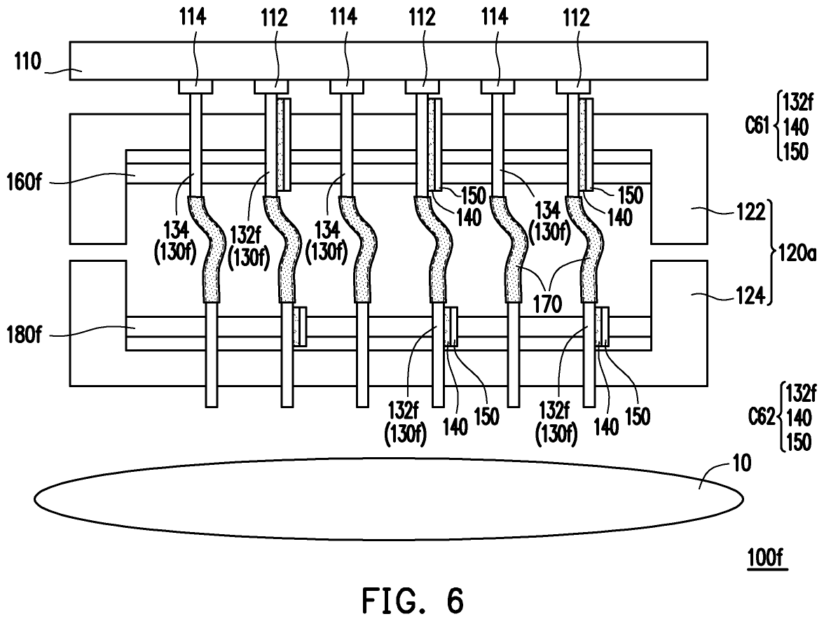

FIG. 6 is a schematic diagram of a probe card according to another embodiment of the disclosure. With reference to both FIG. 4 and FIG. 6, the probe card 100f of this embodiment is similar to the probe card 100d of FIG. 4, and the main difference between the two is that in this embodiment, at least portion of each power prober 132f of the prober 130f, the dielectric layer 140 and the metal layer 150 may define at least one first capacitor (schematically showing a first capacitor C61) and at least one second capacitor (schematically showing a second capacitor C62). The first capacitor C61 penetrates the conductive layer 160f and the first guide plate portion 122 and extends adjacent to the power pad 112, while the second capacitor C62 penetrates another conductive layer 180f. The setting of this second capacitor C62 can be significantly closer to the device under test 10, which can reduce the inductance and improve the test signal integrity and test quality of the probe card 100f, while the setting of this first capacitor C61 can increase the capacitor value.

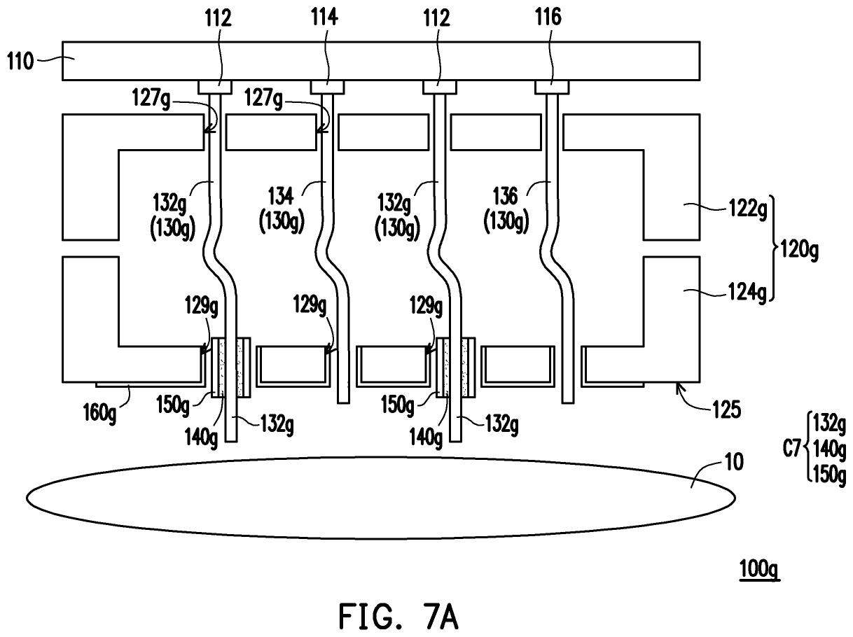

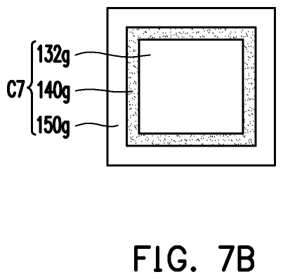

FIG. 7A is a schematic diagram of a probe card according to another embodiment of the disclosure. FIG. 7B is a schematic top view of FIG. 7A. With reference to both FIG. 1 and FIG. 7A, the probe card 100g of this embodiment is similar to the probe card 100a of FIG. 1, and the main difference between the two is that in this embodiment, the first guide plate portion 122g of the guide plate 120g has at least one opening (schematically showing a plurality of openings 127g), and the second guide plate portion 124g has at least one opening (schematically showing a plurality of openings 129g, that is, the first openings). The prober 130g also includes a signal prober 136, which is connected to the signal pad 116 of the adapter plate 110. The power prober 132g, the ground prober 134 and the signal prober 136 of the prober 130g all pass through the openings 127g and the openings 129g. The conductive layer 160g is disposed on the exterior surface 125 of the second guide plate portion 124g that is relatively far away from the adapter plate 110 and extends into the opening 129g. Capacitor C7 defined by at least a portion of each power prober 132g of the prober 130g, the dielectric layer 140g and the metal layer 150g is located in the opening 129g and is spaced apart from the conductive layer 160g. As shown in FIG. 7B, the dielectric layer 140g of this embodiment surrounds the power prober 132g, and the metal layer 150g surrounds the dielectric layer 140g. The dielectric layer 140g and the metal layer 150g are both arranged in a ring shape. In short, this embodiment directly defines the position of the conductive layer 160g on the guide plate 120g through lithography technology or chemical vapor deposition (CVD) technology, etc., and connects the capacitor probe (i.e. the power prober 132g) and a non-capacitor probe (i.e. the ground prober 134) in series with the conductive layer 160g on the guide plate 120g. The setting of this capacitor C7 can be significantly closer to the device under test 10, which can reduce the inductance and improve the test signal integrity and test quality of the probe card 100g.

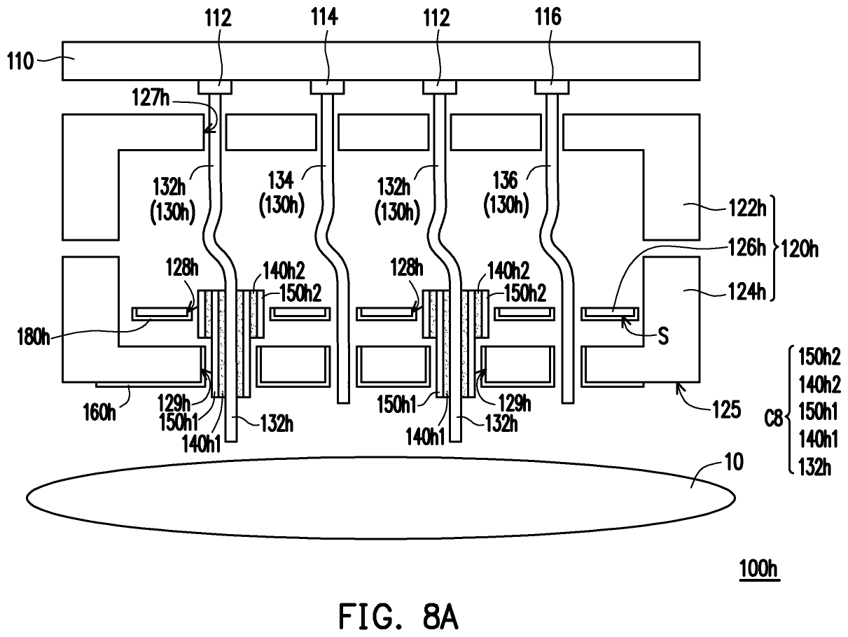

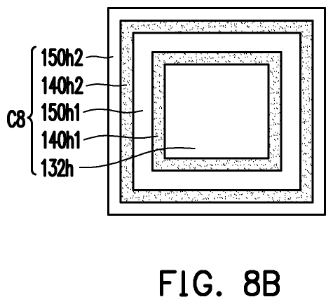

FIG. 8A is a schematic diagram of a probe card according to another embodiment of the disclosure. FIG. 8B is a schematic top view of FIG. 8A. With reference to both FIG. 1 and FIG. 8A, the probe card 100h of this embodiment is similar to the probe card 100a of FIG. 1, and the main difference between the two is that in this embodiment, the probe card 100h also includes another conductive layer 180h, and the guide plate 120h further includes a third guide plate portion 126h. Specifically, the first guide plate portion 122h of the guide plate 120h has at least one opening (schematically showing a plurality of openings 127h), and the second guide plate portion 124h has at least one opening (schematically showing a plurality of openings 129h, that is, the first openings), and the third guide plate portion 126h has at least one opening (schematically showing multiple openings 128h, that is, the second openings). The prober 130h also includes a signal prober 136, which is connected to the signal pad 116 of the adapter plate 110. The power prober 132h, the ground prober 134 and the signal prober 136 of the prober 130h all pass through the openings 127h, the openings 128h and the openings 129h. Herein, the opening 127h, the opening 128h and the opening 129h are set corresponding to each other, and the diameter of the opening 128h is larger than the diameter of the opening 129h. The conductive layer 160h is disposed on the exterior surface 125 of the second guide plate portion 124h relatively far away from the adapter plate 110 and extends into the opening 129h. Another conductive layer 180h is disposed on a surface S of the third guide plate portion 126h relatively far away from the adapter plate 110 and extends into the opening 128h. At least portion of each power prober 132h of prober 130h, the dielectric layer 140h1 and the metal layer 150h1 are located in the opening 129h and the opening 128h, and the dielectric layer 140h2 and the metal layer 150h2 are disposed on the metal layer 150h1 located in the opening 128h. A double-layer capacitor C8 is defined by at least portion of each power prober 132h, the dielectric layer 140h1, the metal layer 150h1, the dielectric layer 140h2 and the metal layer 150h2, and this capacitor C8 is spaced apart from the conductive layer 160h and another conductive layer 180h. As shown in FIG. 8B, the dielectric layer 140h1 of this embodiment surrounds the power prober 132h, the metal layer 150h1 surrounds the dielectric layer 140h1, the dielectric layer 140h2 surrounds the metal layer 150h1, and the metal layer 150h2 surrounds the dielectric layer 140h2. Herein, the dielectric layer 140h1, the metal layer 150h1, the dielectric layer 140h2 and the metal layer 150h2 are all arranged in a ring shape.

In short, this embodiment directly defines the positions of the conductive layer 160h and another conductive layer 180h on the guide plate 120h through lithography technology or chemical vapor deposition process technology (Chemical Vapor Deposition, CVD), etc., and connects the the capacitor probe (i.e. the power prober 132h) and a non-capacitor probe (i.e. the ground prober 134) in series with the conductive layer 160h and another conductive layer 180h one the guide plate 120h. The setting of this capacitor C8 can be significantly closer to the device under test 10, which can reduce the inductance and improve the test signal integrity and test quality of the probe card 100h. In addition, the setting of the double-layer capacitor C8 structure can also increase the capacitor value.

To sum up, in the disclosure, the capacitor on the power prober connects the power prober and the ground prober in series through the conductive layer of the guide plate to form a current loop, wherein the capacitor can provide instant power to the probe card during testing. Compared with the prior art in which the de-coupling capacitor is placed on the adapter plate or the printed circuit board, design of the probe card in the disclosure can greatly shorten the distance between the power supply and the device under test, not only can instantly supply power, but also reduce parasitic inductance, so that the test high voltage (VIH) can be effectively identified, and the test signal can be avoided to avoid blurring of the test signal that leads to misinterpretation, which can improve the integrity of the test signal.

Although the disclosure has been disclosed above through embodiments, they are not intended to limit the disclosure. Anyone with ordinary knowledge in the relevant technical field can make some changes and modifications without departing from the spirit and scope of the disclosure. Therefore, the protection scope of the disclosure shall be determined by the appended patent application scope.

What is claimed is:

1. A probe card configured to test an electrical properties of a device under test, the probe card comprising:
an adapter plate comprising at least one power pad and at least one ground pad;
a guide plate disposed between the adapter plate and the device under test;
a plurality of probes penetrating through the guide plate and electrically connected to the adapter plate, the plurality of probes comprising at least one power prober and at least one ground prober, the at least one power prober electrically connected to the at least one power pad, and the at least one ground probe electrically connected to the at least one ground pad;
at least one capacitor located on at least a portion of the at least one power prober; and
a conductive layer connected to the guide plate, wherein the at least one capacitor connects the at least one power prober and the at least one ground prober in series through the conductive layer to form a current loop.

2. The probe card according to claim 1, further comprising:
a dielectric layer located on the at least a portion of the at least one power probe; and
at least one metal layer disposed on the dielectric layer, wherein when the at least one metal layer is a metal layer, the dielectric layer and the metal layer are sequentially stacked on the at least portion of the at least one power prober, and the at least portion of the at least one power prober, the dielectric layer and the metal layer define the at least one capacitor, or, when the at least one metal layer is two metal layers, the dielectric layer is located between the two metal layers, and the two metal layers and the dielectric layer define the at least one capacitor.

3. The probe card according to claim 1, wherein the guide plate comprises a first guide plate portion and a second guide plate portion, the first guide plate portion and the second guide plate portion are disposed in a hollow ring shape at intervals, the second guide plate portion is located between the first guide plate portion and the device under test, the at least one power prober comprises at least one fixed end and at least one detection end, the at least one fixed end is connected to the at least one power pad, and the at least one detection end is used to contact the device under test.

4. The probe card according to claim 3, wherein the conductive layer is disposed on an exterior surface of the first guide plate portion relatively adjacent to the adapter plate, and the at least one capacitor penetrates the first guide plate portion and is adjacent to the at least one fixed end.

5. The probe card according to claim 3, wherein the conductive layer is disposed on an exterior surface of the second guide plate portion relatively away from the adapter plate, and the at least one capacitor penetrates the second guide plate portion and is adjacent to the at least one detection end.

6. The probe card according to claim 3, further comprising:
an another conductive layer, wherein the conductive layer is connected to an inside of the first guide plate portion, and the another conductive layer is connected to an inside of the second guide plate portion, and the at least one capacitor penetrates the another conductive layer.

7. The probe card according to claim 6, wherein the at least one capacitor comprises at least one first capacitor and at least one second capacitor, the at least one first capacitor penetrates the conductive layer, and the at least one second capacitor penetrates the another conductive layer.

8. The probe card according to claim 7, wherein the at least one first capacitor further penetrates the first guide plate portion and extends adjacent to the at least one power pad.

9. The probe card according to claim 3, wherein the second guide plate portion has at least one first opening, the conductive layer is disposed on an exterior surface of the second guide plate portion relatively far away from the adapter plate and extends into the at least one first opening, and the at least one capacitor is located in the at least one the first opening and spaced apart from the conductive layer.

10. The probe card according to claim 9, further comprising:
an another conductive layer, wherein the guide plate further comprises a third guide plate portion, the third guide plate portion has at least one second opening, the at least one second opening is disposed corresponding to the at least one first opening, and a diameter of the at least one second opening is larger than a diameter of the at least one first opening, the another conductive layer is disposed on a surface of the third guide plate portion relatively away from the adapter plate and extends into the at least one second opening, and the at least one capacitor further extends into the at least one second opening and is spaced apart from the another conductive layer.

11. The probe card according to claim 1, further comprising:
an insulating layer disposed on a portion of each of the plurality of the probes.
